(19) United States
(12) Patent Application Publication
(10) Pub. No.: US 2024/0324432 A1
(43) Pub. Date: Sep. 26, 2024

(54) DISPLAY APPARATUS

(71) Applicant: SAMSUNG DISPLAY CO., LTD., Yongin-si (KR)

(72) Inventor: Yoonki Hong, Yongin-si (KR)

(21) Appl. No.: 18/399,601

(22) Filed: Dec. 28, 2023

(30) Foreign Application Priority Data
Mar. 24, 2023 (KR) 10-2023-0039040
Jul. 26, 2023 (KR) 10-2023-0097703

(51) Int. Cl. H10K 59/90; G06F 3/041; G09G 3/3233; H10K 59/80

(52) U.S. Cl. CPC H10K 59/90; G06F 3/0412; H10K 59/80; G06F 2203/04102; G09G 3/3233; G09G 2300/0426; G09G 2300/0842

(57) ABSTRACT

A display apparatus includes a first substrate, a display layer disposed on the first substrate and including a plurality of pixels, a second substrate disposed on the display layer, a first adhesive layer disposed under the first substrate, a main flexible circuit board having an end portion fixed to the first substrate and a side fixed to the first adhesive layer, a plate portion disposed below the first adhesive layer and fixed to the first adhesive layer, a second adhesive layer disposed below the plate portion, and a touch flexible circuit board having an end portion fixed to the second substrate and a side fixed to the second adhesive layer, wherein the first adhesive layer includes an exposed region exposed from the main flexible circuit board, and the plate portion overlaps the exposed region.

### CROSS-REFERENCE TO RELATED APPLICATIONS

This application claims priority under 35 U.S.C. § 119 to Korean Patent Application No. 10-2023-0039040, filed on Mar. 24, 2023, in the Korean Intellectual Property Office, and Korean Patent Application No. 10-2023-0097703, filed on Jul. 26, 2023, in the Korean Intellectual Property Office, the disclosures of which are incorporated by reference herein in their entirety.

### BACKGROUND

### 1. Technical Field

One or more embodiments relate to a display apparatus, and more particularly, to a display apparatus including a plurality of flexible circuit boards.

### 2. Discussion of Related Art

Mobile electronic devices are widely used for inputting and outputting data. These mobile electronic devices may include tablet PCs, mobile phones, and other small electronic devices.

The mobile electronic devices may include display apparatuses. The display apparatuses may provide visual information such as images or videos to users in order to support various functions. As components for driving the display apparatuses have been miniaturized, proportions of the mobile electronic devices devoted to the display apparatuses has increased, and flexible structures have been developed.

### SUMMARY

One or more embodiments include a display apparatus having a plate portion fixed to a first substrate without a separate adhesive layer for fixing a main flexible circuit board and the plate portion together.

However, objectives of the present disclosure are exemplary, and objectives of the disclosure are not limited thereto.

Additional aspects will be set forth in part in the description and, in part, will be apparent from the description, or may be learned by practice of embodiments of the disclosure.

According to one or more embodiments, a display apparatus includes a first substrate, a display layer disposed on the first substrate and including a plurality of pixels, a second substrate disposed on the display layer, a first adhesive layer disposed under the first substrate, a main flexible circuit board having an end portion fixed to the first substrate and a side fixed to the first adhesive layer, a plate portion disposed below the first adhesive layer and fixed to the first adhesive layer, a second adhesive layer disposed below the plate portion, and a touch flexible circuit board having an end portion fixed to the second substrate and a side fixed to the second adhesive layer, wherein the first adhesive layer includes an exposed region exposed from the main flexible circuit board, and the plate portion overlaps the exposed region.

In the present embodiment, in a plan view, a size of the exposed region may be greater than a size of the plate portion.

In an embodiment, in a plan view, the plate portion may be disposed apart from the main flexible circuit board.

In an embodiment, in a plan view, the touch flexible circuit board may cover the plate portion.

In an embodiment, the touch flexible circuit board may overlap the main flexible circuit board.

In an embodiment, in a plan view, a portion of a corner of the exposed region may be disposed apart from the main flexible circuit board.

In an embodiment, in a plan view, the main flexible circuit board may have a notch shape at a boundary with the exposed region.

In an embodiment, in a plan view, the plate portion may be disposed on the first adhesive layer in the exposed region and the main flexible circuit board may surround the exposed region.

In an embodiment, the display apparatus may further include a cushion layer disposed between the first substrate and the first adhesive layer, and the side of the main flexible circuit board may be fixed to the cushion layer by the first adhesive layer.

In an embodiment, the display apparatus may further include a touch sensing layer disposed on the second substrate, and the one side of the touch flexible circuit board may be fixed to the touch sensing layer.

According to one or more embodiments, a display apparatus may include a first substrate, a display layer disposed on the first substrate and including a plurality of pixels, a second substrate disposed on the display layer, a first adhesive layer disposed under the first substrate, a main flexible circuit board having an end portion fixed to the first substrate and another side fixed to the first adhesive layer, and having a first opening exposing a portion of the first adhesive layer, a plate portion disposed below the first adhesive layer and fixed to the first adhesive layer, and having at least a portion accommodated in the first opening, a second adhesive layer disposed below the plate portion, and a touch flexible circuit board having an end portion fixed to the second substrate and a side fixed to the second adhesive layer.

In an embodiment, in a plan view, the touch flexible circuit board may cover the plate portion.

In an embodiment, in a plan view, the first opening may have a notch shape.

In an embodiment, in a plan view, the plate portion may be disposed on the first adhesive layer in the first opening and the main flexible circuit board may surround the first opening.

In an embodiment, the display apparatus may further include a cushion layer disposed between the first substrate and the first adhesive layer, the first adhesive layer may be disposed between the side of the main flexible circuit board and the cushion layer, and the side of the main flexible circuit board may fixed to the cushion layer by the first adhesive layer.

In an embodiment, the display apparatus may further include a touch sensing layer disposed on the second substrate, and the end portion of the touch flexible circuit board may be fixed to the touch sensing layer.

According to one or more embodiments, a display apparatus may include a first substrate, a display layer disposed on the first substrate, a second substrate disposed on the display layer, a first adhesive layer disposed under the first substrate, a main flexible circuit board comprising a first side surface fixed to the first substrate and fixed to the first adhesive layer, and a first opening exposing the first adhesive layer, a plate portion disposed in the first opening and below the first adhesive layer and fixed to the first adhesive layer in the first opening, a second adhesive layer disposed below the plate portion, and a touch flexible circuit board having a first side surface fixed to the second substrate and fixed to the second adhesive layer.

In an embodiment, in a plan view, the plate portion may be disposed apart from the main flexible circuit board.

In an embodiment, in a plan view, the touch flexible circuit board may cover the plate portion.

In an embodiment the main flexible circuit board may completely surrounds the plate portion in the first opening.

Other aspects, features, and advantages other than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 and FIG. 3 are equivalent circuit diagrams of any one pixel of a display apparatus according to an embodiment;

FIG. 4 is a schematic cross-sectional view of a display apparatus according to an embodiment;

FIG. 5 is a schematic plan view of a portion of a display apparatus according to an embodiment;

FIG. 6 is a schematic cross-sectional view of a portion of a display apparatus according to an embodiment;

FIG. 7 is a schematic plan view of a portion of a display apparatus according to an embodiment; and

FIG. 8 is a schematic cross-sectional view of a portion of a display apparatus according to an embodiment.

### DETAILED DESCRIPTION

Reference will now be made in detail to embodiments, examples of which are illustrated in the accompanying drawings, wherein like reference numerals refer to like elements throughout the specification. In this regard, embodiments may have different forms and should not be construed as being limited to the descriptions set forth herein. Accordingly, embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to embodiments illustrated in the drawings and described in the detailed description section. The effect and features of embodiments, and a method to achieve the same, will be clearer referring to the detailed descriptions herein with the drawings. However, embodiments may be implemented in various forms, and may not be limited to embodiments presented herein.

Hereinafter, embodiments will be described in detail with reference to the accompanying drawings, and in the description with reference to the drawings, the same or corresponding elements are indicated by the same reference numerals and redundant descriptions thereof may be omitted.

In the following embodiment, it will be understood that although the terms “first,” “second,” etc. may be used herein to describe various elements, these elements should not be limited by these terms. These terms are only used to distinguish one element from another.

In the disclosure, the expression of singularity in the present specification includes the plurality unless clearly specified otherwise in context.

In the disclosure, it will be further understood that the terms “comprises” and/or “comprising” used herein specify the presence of stated features or elements, but do not preclude the presence or addition of one or more other features or elements.

In the disclosure, it will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings may be arbitrarily illustrated for convenience of explanation, embodiments are not limited thereto.

In the disclosure, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an embodiment may be implemented differently, a specific process order may be performed differently from the described order. For example, two consecutively described processes may be performed substantially at the same time or performed in an order opposite to the described order.

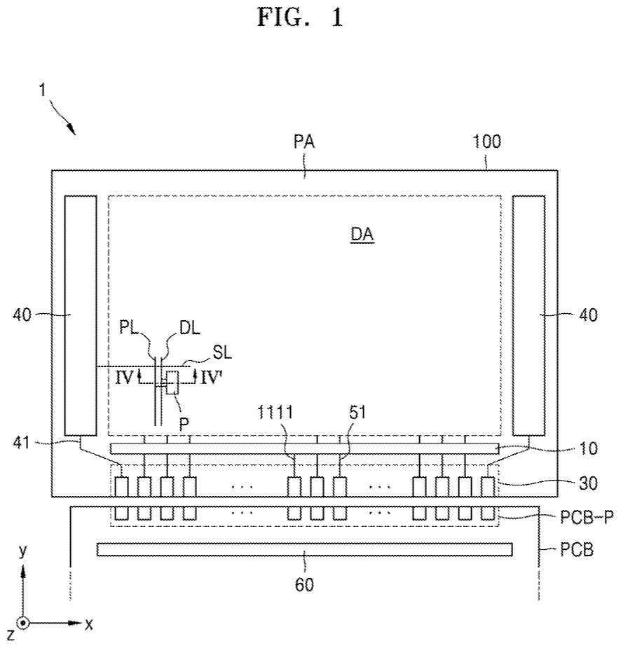

FIG. 1 is a schematic plan view of a display apparatus according to an embodiment.

Referring to FIG. 1, a display apparatus 1 may include a display region DA and a peripheral region PA. The peripheral region PA may be disposed around the display region DA. The display apparatus 1 may generate a certain image by emitting light from a plurality of pixels P. The plurality of pixels P may be disposed in the display region DA.

The display region DA may include a scan line SL extending in an x direction and the pixels P connected to a data line DL extending in a y direction crossing the x direction. Each pixel P may be connected to a driving voltage line PL extending in the y direction.

Each of the pixels P may include a display device such as an organic light-emitting diode OLED. Each pixel P may emit, for example, red light, green light, blue light, or white light via the organic light-emitting diode OLED. The pixel P in the present specification may be understood as a subpixel emitting one of red light, green light, blue light, or white light as described above. In some embodiments, the organic light-emitting diodes OLED included in the pixels P may all emit a same color, and different colors of each pixel P may be implemented by a color filter, or the like disposed on the organic light-emitting diode OLED.

Each pixel P may be electrically connected to embedded circuits disposed in the peripheral region PA. An embedded driving circuit unit 40, a terminal unit 30, a first power supply line 10, and a second power supply line (not shown) may be disposed in the peripheral region PA.

The embedded driving circuit unit 40 may include a plurality of thin-film transistors. The embedded driving circuit unit 40 may provide a scan signal to each pixel P via the scan line SL. The embedded driving circuit unit 40 may be arranged on sides of the display region DA with the display region DA therebetween. Some of the pixels P disposed in the display region DA may be electrically connected with the embedded driving circuit unit 40 disposed on a first side, and the others may be electrically connected with the embedded driving circuit unit 40 arranged on a second side opposite the first side. Referring to FIG. 1, the embedded driving circuit 40 may include pixels disposed on a left side of the display region DA and pixels disposed on a right side of the display region DA. In another embodiment, the embedded driving circuit unit 40 may be arranged on one side of the display region DA.

The terminal unit 30 may be arranged on a side of a substrate 100. The terminal unit 30 may be exposed to an outside. An insulating layer (not shown) may expose the terminal unit 30 to the outside. The terminal unit 30 may be electrically connected with a printed circuit board PCB. A terminal PCB-P of the printed circuit board PCB may be electrically connected with the terminal unit 30.

The printed circuit board PCB may transmit a signal or power of a controller (not shown) to the terminal unit 30. The controller may provide a driving voltage to the first power supply line 10 via a first connection line 1111. The driving voltage may be provided to each pixel P via the driving voltage line P connected with the first power supply line 10. In addition, the controller may provide a common voltage to the second power supply line (not shown). The common voltage may be provided to an opposite electrode of the pixel P, which may be connected with the second power supply line.

A control signal generated by the controller may be transmitted to the embedded driving circuit unit 40 via a third connection line 41 via the printed circuit board PCB.

A data driving circuit 60 may be provided on the printed circuit board PCB. The data driving circuit 60 may be electrically connected to the data line DL. A data signal of the data driving circuit 60 may be provided to each pixel P via a connection line 51 connected to the terminal unit 30 and the data line DL connected with the connection line 51. In another embodiment, the data driving circuit 60 may be disposed on the substrate 100. For example, the data driving circuit 60 may be disposed between the terminal unit 30 and the first power supply line 10.

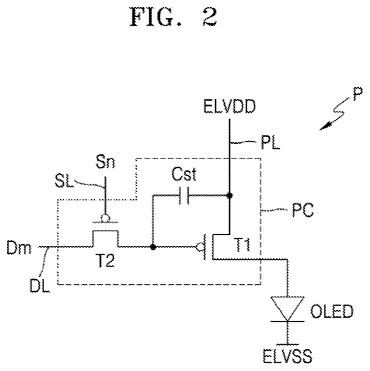

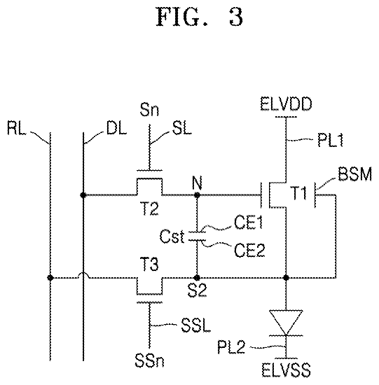

FIG. 2 and FIG. 3 are equivalent circuit diagrams of a pixel of a display apparatus according to an embodiment.

Referring to FIG. 2, each pixel P may include a pixel circuit PC and the organic light-emitting diode OLED. The pixel circuit PC may be connected to the scan line SL and the data line DL. The organic light-emitting diode OLED may be connected to the pixel circuit PC.

The pixel circuit PC may include a driving thin-film transistor T1, a switching thin-film transistor T2, and a storage capacitor Cst. The switching thin-film transistor T2 may be connected to the scan line SL and the data line DL, and may be configured to transmit a data signal Dm input via the data line DL to the driving thin-film transistor T1 according to a scan signal Sn input via the scan line SL.

The storage capacitor Cst may be connected to the switching thin-film transistor T2 and the driving voltage line PL. The storage capacitor Cst may store a voltage corresponding to a difference between a voltage received from the switching thin-film transistor T2 and a driving power voltage ELVDD (or a driving voltage) supplied to the driving voltage line PL.

The driving thin-film transistor T1 may be connected to the driving voltage line PL and the storage capacitor Cst. The driving thin-film transistor T1 may be configured to control a driving current flowing from the driving voltage line PL to the organic light-emitting diode OLED, according to a voltage value stored in the storage capacitor Cst. The organic light-emitting diode OLED may emit light having a certain luminance according to the driving current.

In FIG. 2, a case where the pixel circuit PC includes two thin-film transistors and one storage capacitor is illustrated, but the disclosure is not limited thereto.

Referring to FIG. 3, each pixel P may include the organic light-emitting diode OLED and the pixel circuit PC including a plurality of thin-film transistors configured to drive the organic light-emitting diode OLED. The pixel circuit PC may include the driving thin-film transistor T1, the switching thin-film transistor T2, a sensing thin-film transistor T3, and the storage capacitor Cst.

The scan line SL may be connected to a gate electrode of the switching thin-film transistor T2, the data line DL may be connected to a source electrode of the switching thin-film transistor T2, and a first electrode CE1 of the storage capacitor Cst may be connected to a drain electrode of the switching thin-film transistor T2.

Accordingly, the switching thin-film transistor T2 may be configured to supply a data voltage of the data line DL to a first node N in response to the scan signal Sn from the scan line SL of each pixel P.

A gate electrode of the driving thin-film transistor T1 may be connected to the first node N, a source electrode of the driving thin-film transistor T1 may be connected to a first power line PL1 configured to transmit the driving power voltage ELVDD, and a drain electrode of the driving thin-film transistor T1 may be connected to an anode electrode of the organic light-emitting diode OLED.

Accordingly, the driving thin-film transistor T1 may be configured to adjust a current flowing through the organic light-emitting diode OLED, according to its source-gate voltage, that is, a voltage applied between the driving power voltage ELVDD and the first node N.

A sensing control line SSL may be connected to a gate electrode of the sensing thin-film transistor T3, a source electrode of the sensing thin-film transistor T3 may be connected to a second node S2, and a drain electrode of the sensing thin-film transistor T3 may be connected to a reference voltage line RL. In some embodiments, the sensing thin-film transistor T3 may be controlled by the scan line SL. The sensing thin-film transistor T3 may not be controlled by the sensing control line SSL but.

The sensing thin-film transistor T3 may be configured to sense a potential of the anode electrode of the organic light-emitting diode OLED. The sensing thin-film transistor T3 may be configured to supply a pre-charging voltage from the reference voltage line RL to the second node S2 in response to a sensing signal SSn from the sensing control line SSL, or may be configured to supply a voltage of the anode electrode of the organic light-emitting diode OLED to the reference voltage line RL during a sensing period.

The first electrode CE1 of the storage capacitor Cst may be connected to the first node N, and a second electrode CE2 thereof may be connected to the second node S2. The storage capacitor Cst may store a difference voltage between voltages respectively suppled to the first node N and the second node S2, and supplies the difference voltage as a driving voltage of the driving thin-film transistor T1. For example, the storage capacitor Cst may be charged according to a difference voltage between a voltage of the data signal Dm and a pre-charging voltage Vpre respectively supplied to the first node N and the second node S2.

A bias electrode BSM may be formed to correspond to the driving thin-film transistor T1 and may be connected to the source electrode of the sensing thin-film transistor T3. The bias electrode BSM may receive a voltage in association with a potential of the source electrode of the sensing thin-film transistor T3, and the driving thin-film transistor T1 may be thereby stabilized. In some embodiments, the bias electrode BSM may be connected to a separate bias line without being connected to the source electrode of the sensing thin-film transistor T3.

An opposite electrode (for example, a cathode) of the organic light-emitting diode OLED may receive a common power voltage ELVSS. The organic light-emitting diode OLED may emit light by receiving a driving current from the driving thin-film transistor T1.

Although FIG. 3 illustrates that each pixel P includes signal lines SL, SSL, and DL, the reference voltage line RL, the first power line PL1, and a second power line PL2, the disclosure is not limited thereto. For example, at least one of the signal lines SL, SSL, and DL, and/or the reference voltage line RL, the first power line PL1, and the second power line PL2 may be shared by neighboring pixels.

The pixel circuit PC is not limited to a number of thin-film transistors, a number of storage capacitors, and circuit designs described herein with reference to FIG. 2 and FIG. 3, and the number of thin-film transistors, the number of storage capacitors, and the circuit designs may vary.

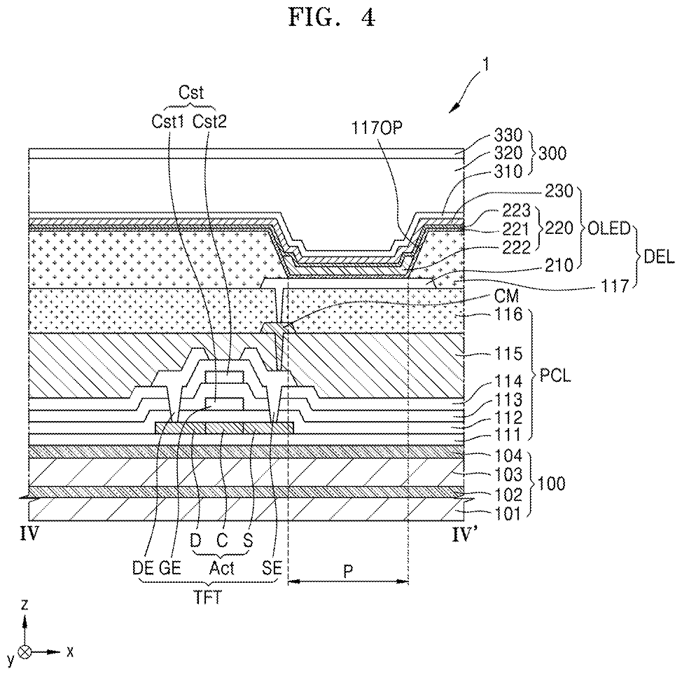

FIG. 4 is a schematic cross-sectional view of a display apparatus according to an embodiment, and may correspond to a cross-section of the display apparatus taken along line IV-IV′ of FIG. 1.

Referring to FIG. 4, the display apparatus 1 may include the substrate 100, a pixel circuit layer PCL, a display element layer DEL, and an encapsulation layer 300. The substrate 100, the pixel circuit layer PCL, the display element layer DEL, and the encapsulation layer 300 may be disposed as a stack structure.

The substrate 100 may have a multilayer structure including a base layer including polymer resin and an inorganic layer. For example, the substrate 100 may include a base layer including polymer resin and a barrier layer that is an inorganic insulating layer. For example, the substrate 100 may include a first base layer 101, a first barrier layer 102, a second base layer 103, and a second barrier layer 104, which may be sequentially stacked. For example, the first barrier layer 102 may be disposed on the first base layer 101, the second base layer 103 may be disposed on the first barrier layer 102, and the second barrier layer 104 may be disposed on the second base layer 103. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), or/and cellulose acetate propionate (CAP). Each of the first barrier layer 102 and the second barrier layer 104 may include an inorganic insulating material, such as silicon oxide, silicon oxynitride, and/or silicon nitride. The substrate 100 may have flexibility. For example, the substrate 100 may be bent, rolled, or folded.

The pixel circuit layer PCL may be disposed on the substrate 100. Referring to FIG. 4, the pixel circuit layer PCL may include a thin-film transistor TFT, a buffer layer 111, a first gate insulating layer 112, a second gate insulating layer 113, an interlayer insulating layer 114, a first planarization insulating layer 115, and a second planarization insulating layer 116. The buffer layer 111, the first gate insulating layer 112, the second gate insulating layer 113, the interlayer insulating layer 114, the first planarization insulating layer 115, and the second planarization insulating layer 116 may be disposed under or/and above constituent elements of the thin-film transistor TFT. The buffer layer 111, the first gate insulating layer 112, the second gate insulating layer 113, the interlayer insulating layer 114, the first planarization insulating layer 115, and the second planarization insulating layer 116 may be sequentially stacked.

The buffer layer 111 may reduce or block penetration of foreign substances, moisture, or external air from under the substrate 100, and may provide a flat surface on the substrate 100. The buffer layer 111 may include an inorganic insulating material, such as silicon oxide, silicon oxynitride, or silicon nitride, and may have a single-layered or multilayer structure including the above-described material.

The thin-film transistor TFT on the buffer layer 111 may include a semiconductor layer Act, and the semiconductor layer Act may include polysilicon (poly-Si). Alternatively, the semiconductor layer Act may include amorphous silicon (a-Si), an oxide semiconductor, or an organic semiconductor. The semiconductor layer Act may include a channel region C, and a drain region D and a source region S respectively disposed at sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti). The gate electrode GE may be formed as a multilayer or single layer including the above-described material.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The ZnOₓ may include zinc oxide (ZnO) and/or zinc peroxide (ZnO₂).

The second gate insulating layer 113 may cover the gate electrode GE. The second gate insulating layer 113, similar to the first gate insulating layer 112, may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The ZnOₓ may include zinc oxide (ZnO) and/or zinc peroxide (ZnO₂).

An upper electrode Cst2 of a storage capacitor Cst may be disposed on the second gate insulating layer 113. The upper electrode Cst2 may overlap the gate electrode GE disposed under the upper electrode Cst2. In this state, the gate electrode GE and the upper electrode Cst2 overlapping each other with the second gate insulating layer 113 disposed therebetween may form the storage capacitor Cst. In other words, the gate electrode GE may function as a lower electrode Cst1 of the storage capacitor Cst.

As such, the storage capacitor Cst and the thin-film transistor TFT may overlap each other in the Z direction. In some embodiments, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer including the above-described material.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The ZnOₓ may include zinc oxide (ZnO) and/or zinc peroxide (ZnO₂). The interlayer insulating layer 114 may be a single layer or multilayer including the above-described inorganic insulating material.

A drain electrode DE and a source electrode SE may each be disposed on the interlayer insulating layer 114. The drain electrode DE may be connected with the drain region D and the source electrode SE may be connected with the source region S via contact holes formed in the insulating layers thereunder. Each of the drain electrode DE and the source electrode SE may include a conductive material. Each of the drain electrode DE and the source electrode SE may include a conductive material including molybdenum (Mo), aluminum (Al), copper (Cu), or titanium (Ti), and may be formed as a multilayer or single layer including the above-described material. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may be disposed on the interlayer insulating layer 114, the drain electrode DE, and the source electrode SE. The first planarization insulating layer 115 may include an organic insulating material, such as a general-purpose polymer such as polymethylmethacrylate (PMMA) or polystyrene (PS), a polymer derivative having a phenolic group, an acrylic polymer, an imide-based polymer, an aryl ether-based polymers, an amide-based polymer, a fluorine-based polymer, a p-xylene-based polymer, a vinyl alcohol-based polymer, or a blend thereof.

The second planarization insulating layer 116 may be disposed on the first planarization insulating layer 115. The second planarization insulating layer 116 may include a same material as that the first planarization insulating layer 115, and may include an organic insulating material, such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

Whereas the first gate insulating layer 112, the second gate insulating layer 113, and the interlayer insulating layer 114 may be conformal layers, the first planarization insulating layer 115, and the second planarization insulating layer 116 cover the thin-film transistor TFT and may have flat upper surfaces.

The display element layer DEL may be disposed on the pixel circuit layer PCL having the above-described structure. The display element layer DEL may include an organic light-emitting diode OLED as a display element (that is, a light-emitting element). The organic light-emitting diode OLED may include a stack including a pixel electrode 210, an intermediate layer 220, and a common electrode 230. The organic light-emitting diode OLED may emit light, for example, red light, green light, or blue light, or red light, green light, blue light, or white light. The organic light-emitting diode OLED may emit light via an emission region, where the emission region may be defined as the pixel P.

The pixel electrode 210 of the organic light-emitting diode OLED may be electrically connected with the thin-film transistor TFT via contact holes formed in the second planarization insulating layer 116 and the first planarization insulating layer 115 and a contact metal CM disposed on the first planarization insulating layer 115. A contact hole in the second planarization insulating layer 116 may overlap a contact hole in the first planarization insulating layer 115, and the organic light-emitting diode OLED may be electrically connected with the thin-film transistor TFT via the contact holes formed in the second planarization insulating layer 116 and the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a film including ITO, IZO, ZnO, or In₂O₃ above/under the above-described reflective film.

A bank layer 117 having an opening 117OP that exposes a center portion of the pixel electrode 210, and may be disposed on the pixel electrode 210. The bank layer 117 may include an organic insulating material and/or an inorganic insulating material. The opening 117OP may define an emission region of light emitted from the organic light-emitting diode OLED. For example, a size/width of the opening 117OP may correspond to a size/width of the emission region. Therefore, the size and/or width of the pixel P may depend on the size and/or width of the opening 117OP of the bank layer 117.

The intermediate layer 220 may include an emission layer 222 disposed on the pixel electrode 210. The emission layer 222 may include a polymer or low molecular weight organic material that emits light of a certain color. Alternatively, the emission layer 222 may include an inorganic light-emitting material or quantum dots.

In an embodiment, the intermediate layer 220 may include a first functional layer 221 and a second functional layer 223. The first functional layer 221 may be disposed below the emission layer 222 and the second functional layer 223 may be disposed on the emission layer 222. The emission layer 222 may be disposed between the first functional layer 221 and the second functional layer 223. The first functional layer 221 may include, for example, a hole transport layer (HTL), or a HTL and a hole injection layer (HIL). The second functional layer 223 that is disposed on the emission layer 222 may include an electron transport layer (ETL) and/or an electron injection layer (EIL). The first functional layer 221 and/or the second functional layer 223, like the common electrode 230 described below, may be a common layer that is formed to cover the substrate 100. For example, the first functional layer 221 and/or the second functional layer 223 may entirely cover the substrate.

The common electrode 230 may be disposed above the pixel electrode 210 and may overlap the pixel electrode 210. The common electrode 230 may include a conductive material having a low work function. For example, the common electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 230 may further include a layer including ITO, IZO, ZnO, or In₂O₃ disposed on the (semi-)transparent layer including the above-described material. The common electrode 230 may be integrally formed to entirely cover the substrate 100.

The encapsulation layer 300 may be disposed on the display element layer DEL and may cover the display element layer DEL. The encapsulation layer 300 may include at least one an inorganic encapsulation layer and at least one organic encapsulation layer. In an embodiment, FIG. 4 illustrates that the encapsulation layer 300 may include a first inorganic encapsulation layer 310, an organic encapsulation layer 320, and a second inorganic encapsulation layer 330, which may be sequentially stacked. The first inorganic encapsulation layer 310 may be disposed on the organic light-emitting diode OLED, the organic encapsulation layer 320 may be disposed on the first inorganic encapsulation layer 310, and the second inorganic encapsulation layer 330 may be disposed on the organic encapsulation layer 320.

Each of the first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, or silicon oxynitride. The organic encapsulation layer 320 may include a polymer-based material. The polymer-based material may include acrylic resin, epoxy-based resin, polyimide, or polyethylene. In an embodiment, the organic encapsulation layer 320 may include acrylate. The organic encapsulation layer 320 may be formed by curing a monomer or applying a polymer. The organic encapsulation layer 320 may be formed of a transparent material.

Although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce the reflectance of light (external light) incident on the display apparatus, and/or may improve the color purity of light emitted from the display apparatus. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals arranged in a certain array. Each of the retarder and the polarizer may further include a protective film.

An adhesive member may be disposed between the touch electrode layer and the optical functional layer. The adhesive member may be any material generally known in the related art without limitation. The adhesive member may be a pressure sensitive adhesive (PSA).

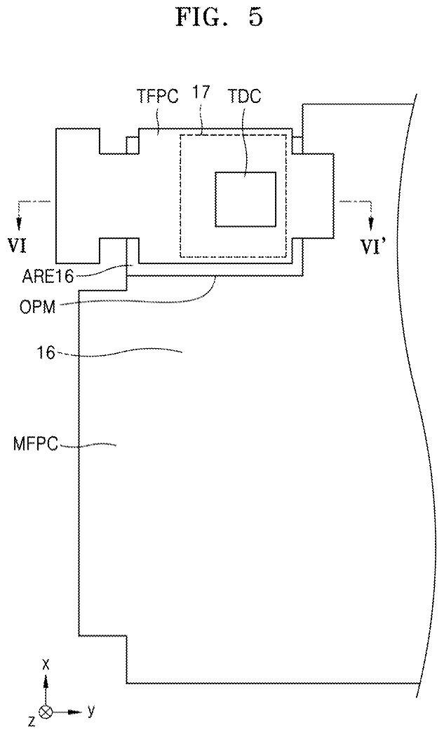

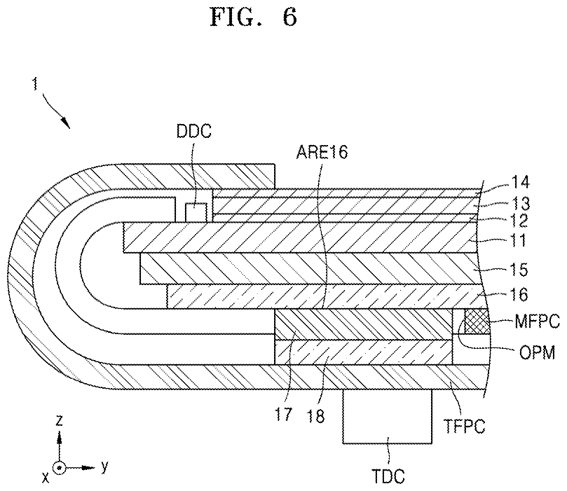

FIG. 5 is a schematic plan view of a portion of a display apparatus according to an embodiment FIG. 6 is a schematic cross-sectional view of a portion of a display apparatus according to an embodiment. FIG. 6 may correspond to portion VI-VI′ of FIG. 5.

Referring to FIG. 5 and FIG. 6, the display apparatus 1 may include a first substrate 11, a display layer 12, a second substrate 13, a touch sensing layer 14, a cushion layer 15, a first adhesive layer 16, a main flexible circuit board MFPC, a plate portion 17, a second adhesive layer 18, a touch flexible circuit board TFPC, a display driving chip DDC, and a touch driving chip TDC.

The display layer 12 may be disposed on the first substrate 11. The first substrate 11 may correspond to the substrate 100 described with reference to FIG. 4. The display layer 12 may include a plurality of pixels and may correspond to the pixel circuit layer PCL and the display element layer DEL, which are described with reference to FIG. 4.

The second substrate 13 may be disposed on the display layer 12. The second substrate 13 may be an encapsulation substrate. The second substrate 13 may reduce or prevent penetration of moisture and/or oxygen from the outside.

The touch sensing layer 14 may be disposed on the second substrate 13. The touch sensing layer 14 may include a touch electrode and a touch signal line configured to transmit and/or receive a signal to and/or from the touch electrode. The touch sensing layer 14 may sense a touch in various ways. For example, the touch sensing layer 14 may sense a touch using a resistive type sensor, a capacitive type sensor, an electro-magnetic type (EM) sensor, or an optical type sensor.

The cushion layer 15 may be disposed below the first substrate 11. The first substrate 11 may be disposed between the cushion layer 15 and the display layer 12. The cushion layer 15 may be disposed on a rear surface of the first substrate 11 and may be fixed to the first substrate 11. The cushion layer 15 may be disposed between the first substrate 11 and the first adhesive layer 16. The cushion layer 15 may support the first substrate 11 and may protect the first substrate 11 from external impact. The cushion layer 15 may include a material having elasticity.

The first adhesive layer 16 may be disposed below the cushion layer 15, and the plate portion 17 may be disposed below the first adhesive layer 16. The first adhesive layer 16 may be disposed between the first substrate 11 and the plate portion 17. The first adhesive layer 16 may bond the cushion layer 15 and the plate portion 17 together such that no air layer or the like is formed therebetween. The first substrate 11 and the cushion layer 15 may be fixed to each other and the plate portion 17 may be fixed to the cushion layer 15 by the first adhesive layer 16, and the first adhesive layer 16 may indirectly fix the first substrate 11 and the plate portion 17 together.

The plate portion 17 may be disposed under the first substrate 11 so as to be fixed to the first adhesive layer 16. The plate portion 17 may function as a heat dissipation plate. The plate portion 17 may efficiently dissipate heat. The plate portion 17 may transfer heat downward and away from the second substrate 13. For example, the plate portion 17 may include a metal material having high thermal conductivity, such as stainless steel, copper, nickel, ferrite, silver, or aluminum.

An end portion of the main flexible circuit board MFPC may be fixed to the first substrate 11, and a side of the main flexible circuit board MFPC may be fixed to the first adhesive layer 16. The side of the main flexible circuit board MFPC may be fixed to the cushion layer 15 by the first adhesive layer 16. The main flexible circuit board MFPC may include a flexible material and may be fixed to the first substrate 11 and the first adhesive layer 16 while being bent. A first side surface of the main flexible circuit board MFPC may be fixed to the first substrate 11 and the first adhesive layer 16, wherein the main flexible circuit board MFPC may be bent to the first substrate 11 disposed above the first adhesive layer 16. A signal for controlling the display layer 12 and the display driving chip DDC may be applied via the main flexible circuit board MFPC.

The first adhesive layer 16 may include an exposed region ARE16 exposed from the main flexible circuit board MFPC. In FIG. 5, in a plan view, the exposed region ARE16 may not overlap the main flexible circuit board MFPC. The exposed region ARE16 may be disposed at a periphery of the main flexible circuit board MFPC.

A first opening OPM exposing a portion of the first adhesive layer 16 may be disposed in the main flexible circuit board MFPC. In a plan view, the exposed region ARE16 and the first opening OPM may overlap each other. The plate portion 17 may overlap the exposed region ARE16. At least a portion of the plate portion 17 may be accommodated in the first opening OPM and may be fixed to the first adhesive layer 16 in the exposed region ARE16.

In a plan view, a size of the exposed region ARE16 and a size of the first opening OPM may be greater than a size of the plate portion 17. Accordingly, the plate portion 17 may be disposed apart from the main flexible circuit board MFPC. In a plan view, a portion of a corner of the exposed region ARE16 may be disposed apart from the main flexible circuit board MFPC. In other words, in a plan view, the first opening OPM may be disposed at an end portion of the main flexible circuit board MFPC. For example, in a plan view, the main flexible circuit board MFPC may have a notch shape at a boundary with the exposed region ARE16.

The second adhesive layer 18 may be disposed below the plate portion 17. The second adhesive layer 18 may bond the plate portion 17 and the touch flexible circuit board TFPC together such that no air layer or the like is formed therebetween. The first substrate 11 and the plate portion 17 may be fixed to each other by the first adhesive layer 16, and the plate portion 17 may be fixed to the touch flexible circuit board TFPC by the second adhesive layer 18, the second adhesive layer 18 may indirectly fix the first substrate 11 and the touch flexible circuit board TFPC.

An end portion of the touch flexible circuit board TFPC may be fixed to the second substrate 13, and a side of the touch flexible circuit board TFPC may be fixed to the second adhesive layer 18. For example, the touch flexible circuit board TFPC may be indirectly fixed to the second substrate 13 in such a manner that the end portion of the touch flexible circuit board TFPC is fixed to the touch sensing layer 14 disposed on the second substrate 13. A first side surface of the touch flexible circuit board TFPC may be fixed to the second substrate 13 and the second adhesive layer 18, wherein the touch flexible circuit board TFPC may be bent to the second substrate 13 disposed above the second adhesive layer 18. The touch flexible circuit board TFPC may transmit a signal from the touch sensing layer 14 or may receive a signal from the touch sensing layer 14. In FIG. 5, in a plan view, the touch flexible circuit board TFPC may cover the plate portion 17. The touch flexible circuit board TFPC may overlap the main flexible circuit board MFPC.

The display driving chip DDC may be fixed to the first substrate 11 and electrically connected with the first substrate 11. The display driving chip DDC may include driving apparatuses such as a data driving unit for applying a data voltage to a data line, a gate driving unit for applying a gate-on voltage to a gate line, and a signal controller for controlling the operation of the data driving unit and the gate driving unit.

The touch driving chip TDC may be fixed to the touch flexible circuit board TFPC and electrically connected with the touch flexible circuit board TFPC. The touch driving chip TDC may transmit a touch signal to the touch sensing layer 14. In addition, the touch driving chip TDC may receive a touch signal from the touch sensing layer 14 and generate information such as the presence or absence of a touch and a touch location.

According to embodiments described with reference to FIG. 5 and FIG. 6, the plate portion 17 may not be directly fixed to the main flexible circuit board MFPC, and thus, a separate adhesive layer for fixing the plate portion 17 and the main flexible circuit board MFPC together may be omitted. Therefore, the manufacturing cost of the display apparatus 1 may be reduced. In addition, the plate portion 17 may be fixed to the first adhesive layer 16 while being accommodated in the first opening OPM, and thus, the thickness of the display apparatus 1 may be reduced.

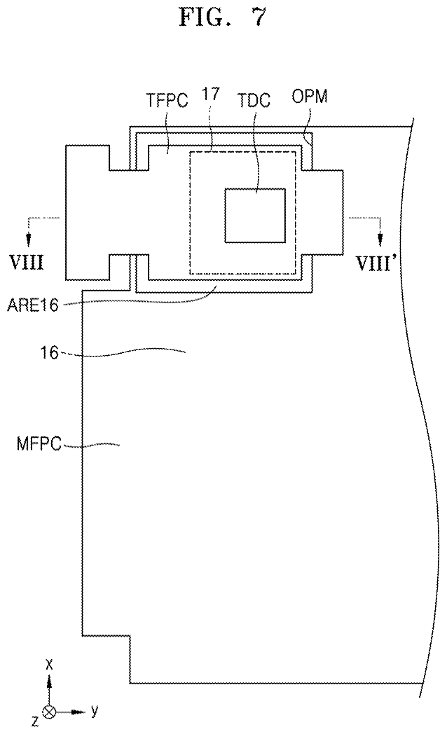

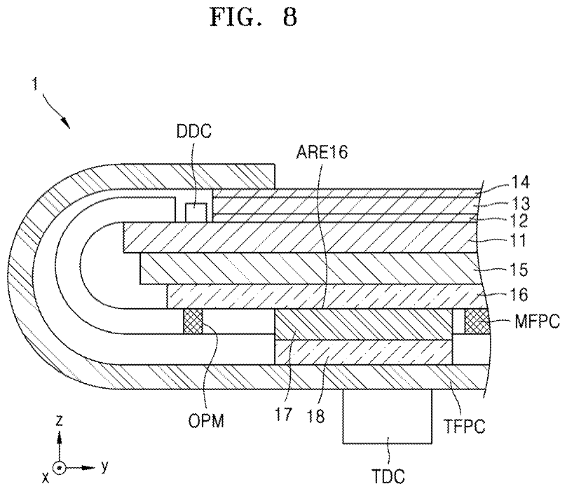

FIG. 7 is a schematic plan view of a portion of a display apparatus according to an embodiment. FIG. 8 is a schematic cross-sectional view of a portion of a display apparatus according to an embodiment. FIG. 8 may correspond to portion VIII-VIII′ of FIG. 7.

Referring to FIG. 7 and FIG. 8, the display apparatus 1 may include the first substrate 11, the display layer 12, the second substrate 13, the touch sensing layer 14, the cushion layer 15, the first adhesive layer 16, the main flexible circuit board MFPC, the plate portion 17, the second adhesive layer 18, the touch flexible circuit board TFPC, the display driving chip DDC, and the touch driving chip TDC.

The same reference numerals in FIG. 5, FIG. 6, FIG. 7, and FIG. 8 denote the same members, and thus, repeated descriptions thereof may be omitted.

In FIG. 7, in a plan view, the main flexible circuit board MFPC may surround the exposed region ARE16. In other words, the main flexible circuit board MFPC may surround the first opening OPM. Referring to FIG. 8, the plate portion 17 may be disposed in the first opening OPM. The plate portion 17 may be completely surrounded, in a plan view, in the first opening OPM by the main flexible circuit board MFPC. The cushion layer 15 may be disposed over the first opening OPM, and at least a portion of the touch flexible circuit board TFPC may be disposed below the first opening OPM. However, embodiments described with reference to FIG. 5, FIG. 6, FIG. 7, and FIG. 8 are merely examples, and each of the exposed region ARE16 and the first opening OPM may have various shapes.

According to embodiments, manufacturing costs of a display apparatus may be reduced, and the thickness thereof may be reduced.

It should be understood that embodiments described herein should be considered in a descriptive sense only and not for purposes of limitation. Descriptions of features or aspects within embodiments should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first substrate;
a display layer disposed on the first substrate and comprising a plurality of pixels;
a second substrate disposed on the display layer;
a first adhesive layer disposed under the first substrate;
a main flexible circuit board having an end portion fixed to the first substrate and a side fixed to the first adhesive layer;
a plate portion disposed below the first adhesive layer and fixed to the first adhesive layer;
a second adhesive layer disposed below the plate portion; and
a touch flexible circuit board having an end portion fixed to the second substrate and a side fixed to the second adhesive layer,
wherein the first adhesive layer comprises an exposed region exposed from the main flexible circuit board, and
the plate portion overlaps the exposed region.

2. The display apparatus of claim 1, wherein, in a plan view, a size of the exposed region is greater than a size of the plate portion.

3. The display apparatus of claim 1, wherein, in a plan view, the plate portion is disposed apart from the main flexible circuit board.

4. The display apparatus of claim 1, wherein, in a plan view, the touch flexible circuit board covers the plate portion.

5. The display apparatus of claim 1, wherein the touch flexible circuit board overlaps the main flexible circuit board.

6. The display apparatus of claim 1, wherein, in a plan view, a portion of a corner of the exposed region is disposed apart from the main flexible circuit board.

7. The display apparatus of claim 6, wherein, in a plan view, the main flexible circuit board has a notch shape at a boundary with the exposed region.

8. The display apparatus of claim 1, wherein, in a plan view, the plate portion is disposed on the first adhesive layer in the exposed region and the main flexible circuit board surrounds the exposed region.

9. The display apparatus of claim 1, further comprising a cushion layer disposed between the first substrate and the first adhesive layer, wherein the side of the main flexible circuit board is fixed to the cushion layer by the first adhesive layer.

10. The display apparatus of claim 1, further comprising a touch sensing layer disposed on the second substrate, wherein the end portion of the touch flexible circuit board is fixed to the touch sensing layer.

11. A display apparatus comprising:
a first substrate;
a display layer disposed on the first substrate and comprising a plurality of pixels;
a second substrate disposed on the display layer;
a first adhesive layer disposed under the first substrate;
a main flexible circuit board having an end portion fixed to the first substrate and a side fixed to the first adhesive layer, and having a first opening exposing a portion of the first adhesive layer;
a plate portion disposed below the first adhesive layer and fixed to the first adhesive layer, and having at least a portion accommodated in the first opening;
a second adhesive layer disposed below the plate portion; and
a touch flexible circuit board having an end portion fixed to the second substrate and a side fixed to the second adhesive layer.

12. The display apparatus of claim 11, wherein, in a plan view, the touch flexible circuit board covers the plate portion.

13. The display apparatus of claim 11, wherein, in a plan view, the first opening has a notch shape.

14. The display apparatus of claim 11, wherein, in a plan view, the plate portion is disposed on the first adhesive layer in the first opening and the main flexible circuit board surrounds the first opening.

15. The display apparatus of claim 11, further comprising a cushion layer disposed between the first substrate and the first adhesive layer, wherein the first adhesive layer is disposed between the side of the main flexible circuit board and the cushion layer, and the side of the main flexible circuit board is fixed to the cushion layer by the first adhesive layer.

16. The display apparatus of claim 11, further comprising a touch sensing layer disposed on the second substrate, wherein the end portion of the touch flexible circuit board is fixed to the touch sensing layer.

17. A display apparatus comprising:
a first substrate;
a display layer disposed on the first substrate;
a second substrate disposed on the display layer;
a first adhesive layer disposed under the first substrate;
a main flexible circuit board comprising a first side surface fixed to the first substrate and fixed to the first adhesive layer, and a first opening exposing the first adhesive layer;
a plate portion disposed in the first opening and below the first adhesive layer and fixed to the first adhesive layer in the first opening;
a second adhesive layer disposed below the plate portion; and
a touch flexible circuit board having a first side surface fixed to the second substrate and fixed to the second adhesive layer.

18. The display apparatus of claim 17, wherein, in a plan view, the plate portion is disposed apart from the main flexible circuit board.

19. The display apparatus of claim 17, wherein, in a plan view, the touch flexible circuit board covers the plate portion.

20. The display apparatus of claim 17, wherein the main flexible circuit board completely surrounds the plate portion in the first opening.
